(19) United States
(12) Patent Application Publication
(10) Pub. No.: US 2019/0203336 A1
(43) Pub. Date: Jul. 4, 2019

(54) MASK AND MANUFACTURING METHOD THEREOF, DISPLAY PANEL AND MANUFACTURING METHOD THEREOF

(71) Applicants: BOE TECHNOLOGY GROUP CO., LTD., Beijing (CN); CHENGDU BOE OPTOELECTRONICS TECHNOLOGY CO., LTD., Sichuan (CN)

(72) Inventors: Peng XU, Beijing (CN); Jianpeng WU, Beijing (CN)

(21) Appl. No.: 16/111,272

(22) Filed: Aug. 24, 2018

(30) Foreign Application Priority Data
Jan. 2, 2018 (CN) 201810002704.0

(51) Int. Cl. C23C 14/04; C23C 14/24

(52) U.S. Cl. CPC C23C 14/042; C23C 14/24

(57) ABSTRACT

The present disclosure relates to a mask and a method of manufacturing the same, a display panel and a method of manufacturing the same. The mask of the present disclosure includes a base mark unit and at least one connecting member, wherein the base mark unit includes a first connecting region, and the connecting member, which is superposed on the base mole unit, includes a second connecting region and a non-connecting region, wherein the first connecting region of the base mark unit is connected to the second connecting region of the connecting member, and a shape of the non-connecting region and a shape of the base mark unit form a desired target shape of the mask.

### CROSS REFERENCE TO RELATED APPLICATIONS

This application claims the benefit of China Patent Application No. 201810002704.0 filed with the China Patent Office on Jan. 2, 2018, the entire content of which is hereby incorporated by reference.

### TECHNICAL FIELD

The present disclosure relates to the technical field of mold making, and more particularly, to a mask and a manufacturing method thereof, a display panel and a manufacturing method thereof.

### BACKGROUND

With the development of technology and trend, display panels of various electronic devices are also undergoing rapid changes. In order to meet different requirements and aesthetics, device manufacturers will design different appearances for display panels of a certain size and produce display panels having different appearances. An important process in manufacturing of a display panel is to coat a film on a substrate of the display panel by vapor deposition, such as evaporation, wherein a mask is used to shield a position at which no coating is required so as to determine positions for the coating.

### SUMMARY

The present disclosure mainly provides the following technical solutions:

In a first aspect, the present disclosure provides a mask, including: a base mark unit and at least one connecting member, which are provided in a laminating manner. The base mark unit includes a first connecting region, and the connecting member includes a second connecting region and a non-connecting region, the first connecting region of the base mark unit is connected to the second connecting region of the connecting member, and a shape of the non-connecting region and a shape of the base mark unit form a desired target shape of the mask.

In a second aspect, the present disclosure provides a method of manufacturing a mask, the method including: performing an etching to a first mask to obtain a base mark unit having a first connecting region; performing a patterning process to fabricate a connecting member having a second connecting region, wherein the second connecting region is connected to the first connecting region; and assembling the base mark unit and the connecting member by connecting the first connecting region to the second connecting region to form a second mask.

In a third aspect, the present disclosure provides a method of manufacturing a display panel, which includes a display substrate, the method including: forming a first film on the display substrate; and performing a patterning process on the first film by using the mask as described in the first aspect to form a first pattern.

In a fourth aspect, the present disclosure provides a display device including a display panel, which is fabricated by the method for manufacturing a display panel as described in the third aspect.

With the above-described technical solutions, a mask and a manufacturing method thereof, a display panel and a manufacturing method, the present disclosure have at least the following advantages:

With the mask provided by the embodiment of the present disclosure, in order to reduce the waste of resources caused when the mask is fabricated, a set of masks applicable to display panels having various shapes can be provided to enhance compatibility of the masks. The embodiment of the present disclosure replaces the conventional mask, which is integrally formed as having an abnormal shape, with a splice-type mask having a plurality of components. With the splice-type mask, masks having different shapes may be formed by connecting and laminating the base mark unit and the connecting members having different shapes. When a shape of a display panel is changed, it only needs to replace a connecting member with a different one to form a shape that is necessary for a new display panel, and then the base mark unit and the connecting members are assembled to form a mask suitable for the new display panel, thereby saving mask manufacturing resources.

The foregoing description is merely an overview of the technical solutions of the present disclosure. In order that the technical means of the present disclosure is more clearly understood, and be implemented according to the contents of the specification, the preferred embodiments of the present disclosure will be described below in detail in conjunction with the accompanying drawings.

### BRIEF DESCRIPTION OF THE DRAWINGS

Other various advantages and benefits will become apparent to those of ordinary skill in the art by reading the following detailed description of the preferred embodiments. The drawings are only for purposes of illustrating the preferred embodiments and are not considered as limiting the present disclosure. Also, throughout the drawings, like reference numerals refer to like parts. In the drawing:

FIG. 1 shows a base mark unit of a mask according to an embodiment of the present disclosure;

FIG. 2 shows a connecting member of a mask according to an embodiment of the present disclosure;

FIG. 3 shows another connecting member of a mask according to an embodiment of the present disclosure;

FIG. 4 is a diagram illustrating a result of splicing a base mark unit and a connecting member according to an embodiment of the present disclosure;

FIG. 5 shows a base mark unit of a mask, the base mark unit having a positioning device, according to an embodiment of the present disclosure;

FIG. 6 shows another base mark unit of a mask, the base mark unit having a positioning device, according to an embodiment of the present disclosure;

FIG. 7 shows a cross-sectional view of a base mark unit having a positioning device according to an embodiment of the present disclosure;

FIG. 8 shows a connecting member of a mask, the connecting member having a positioning device, according to an embodiment of the present disclosure;

FIG. 9 is a schematic structural view showing another connecting member of a mask, the connecting member having a positioning device, according to an embodiment of the present disclosure;

FIG. 10 is a cross-sectional view showing a connecting member having a positioning device according to an embodiment of the present disclosure;

FIG. 11 is a diagram illustrating a result of splicing a base mark unit and a connecting member which have positioning devices according to an embodiment of the present disclosure;

FIG. 12 is a diagram illustrating another result of splicing a base mark unit and a connecting member which have positioning devices according to an embodiment of the present disclosure;

FIG. 13 is a flowchart showing a method of manufacturing a mask according to an embodiment of the present disclosure; and

FIG. 14 is a flowchart showing another method of manufacturing a mask according to an embodiment of the present disclosure.

### DETAILED DESCRIPTION

In order to further elaborate the technical means and efficacy adopted by the present disclosure for achieving the intended purpose, detailed embodiments, structures, features, and efficacies of a mask and a manufacturing method thereof, a display panel and a manufacturing method thereof provided by the present disclosure will be described in detail below in conjunction with the accompanying drawings and the preferred embodiments. In the following description, different expression “an embodiment” or “embodiment” does not necessarily mean the same embodiment. In addition, specific features, structures, or characteristics in one or more embodiments may be combined in any suitable form.

Because display panels have different shapes, the positions of the films coated on the glass substrates are also different, and shapes of applicable masks are also different. After a conventional mask is manufactured, the shielded region by the mask is constant, so a kind of mask may only be applied to a display panel having the corresponding kind of shape. However, a modern design is updated very rapidly, and after a display panel having a new shape is designed, the mask for the original display panel can no longer be used, and a new mold need to be made so as to manufacture a new mask, which causes a great waste of resources. In addition, for a display panel of a kind of size, every time another appearance is designed, a mask having a shape corresponding to the appearance is required to be separately manufactured. Although there are often only minor differences among different designs for a display panel, it is still required to manufacture a mask with respect to the small changes, which causes the waste of resources.

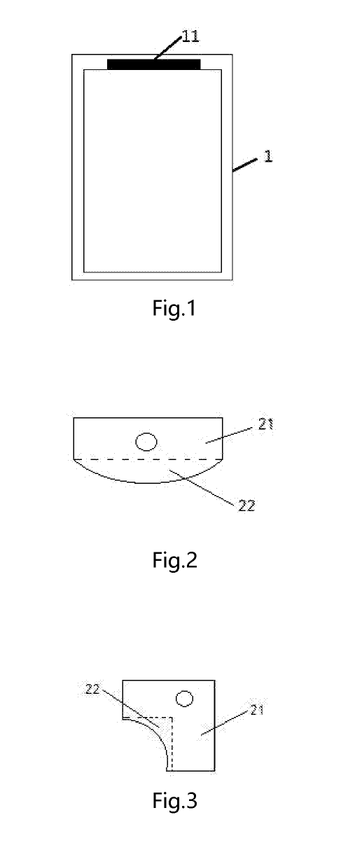

In order to solve the problem of serious waste of resources when making mask in existing technology an embodiment of the present disclosure provides a mask, as shown in FIGS. 1-4.

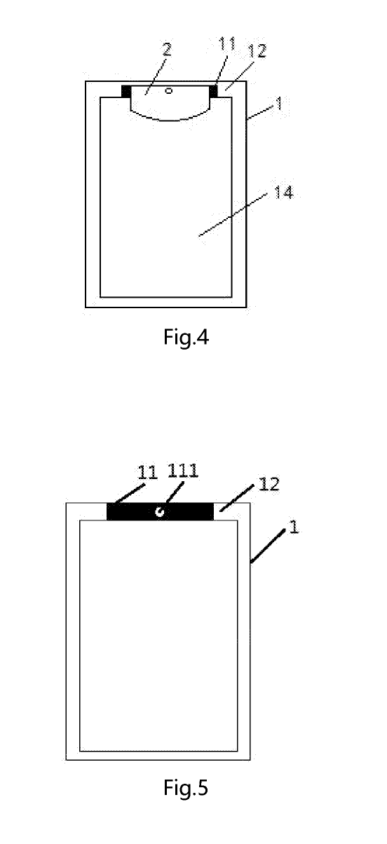

The mask includes a base mark unit 1 and at least one laminated connecting member 2. The present embodiment does not have, for the laminated base mark unit 1 and the connecting member 2, any specific limitations on the manner of superposing, and the superposed number of the connecting members 2. As shown in FIG. 1, the base mark unit 1 includes a first connecting region 11, which is a region of the base mark unit 1 to be connected to the connecting member 2. A shape of the base mark unit 1 is the same as that of a standard mask. The standard mask is of a regular shape, including a rectangular shape, a square shape, a circular shape, or the like. As shown in FIGS. 2 and 3, the connecting member 2 includes a second connecting region 21 and a non-connecting region 22. The non-connecting region 22 of the connecting member 2 has an abnormal shape, which is not the above described regular shape and is determined according to a difference between a target shape and a shape of the base mark unit 1. The target shape is a shape of the mask applicable to a current display panel. As shown in FIG. 2, the non-connecting region 22 of the connecting member 2 may be of an abnormal shape having an arc-shaped protrusion. As shown in FIG. 3, the non-connecting region 22 of the connecting member 2 may also be of an abnormal shape having an arc-shaped corner. The abnormal shape of the non-connecting region 22 is not specifically limited by the preset embodiment. As shown in FIG. 4, the first connecting region 11 of the base mark unit 1 is connected to the second connecting region 21 of the connecting member 2, so that the second region 21 overlaps with the first region 11, and the non-connecting region 22 is exposed outside the base mark unit 1, and a shape of the non-connecting region 22 and the shape of the base mark unit 1 form the target shape, so as to form the mask applicable to the current display panel. Specifically, the first connecting region 11 of the base mark unit 1 and the second connecting region 21 of the connecting member 2 are connected and superposed, and the base mark unit 1 may be used as a bottom layer and the first connecting region 11 of the base mark unit 1 is stacked with a corresponding connecting member 2. Alternatively, the base mark unit 1 may be used as a bottom layer, and the first connecting region 11 is superimposed with a plurality of connecting members 2 at the same position thereof, and the plurality of connecting members 2 form an abnormal shape at the first connecting region 11. Alternatively, the base mark unit 1 may be used as a bottom layer, and the first connecting region 11 is stacked with a connecting member 2 respectively at different positions. A region 14 unshielded by the mask is an open region a shape of which is determined based on a combined shape of the base mark unit 1 and the connecting member 2 after they are spliced. In order to keep relative positions of the first connecting region 11 and the second connecting region 21 unchanged after they are connected, the first connecting region 11 and the second connecting region 21 may be connected in an adhesive manner, an engagement manner, or a screwed-connection manner. The present embodiment does not have any specific limitations on the connection manner, but it should be noted that the connection manner is a detachable connection manner.

Due to the limitations of mask manufacturing processes, as compared to a splice-type mask having a plurality of components, an integrally formed mask with an abnormal shape is not only very difficult to manufacture but also has a low precision for the region in the abnormal shape, as shown in the following table:

Precision Reference Table

| | Precision of | Precision of |
|---|---|---|
| | Region Having | Region Having |
| Type | Standard Shape | Abnormal shape |
| Integrally formed mask with an | ±50 μm | ±100 μm |
| abnormal shape | | |
| Separate connecting member | / | ±20 μm |
| with an abnormal shape | | |
| Splice-type mask having a | ±50 μm | about ±55 μm |
| plurality of components | | |

The precision of the region having an abnormal shape in the splice-type mask having a plurality of components is specifically calculated as follows: since the precision of assembling and aligning the connecting member 2 and the base mark unit 1 is ±10 μm, the precision of the region having an abnormal shape in the splice-type mask having a plurality of components is calculated according to an assembly tolerance:

\sqrt{50²+20²+10²}=54.8 um≈55 um

It can be seen from this, after the base mark unit 1 and the connecting member 2 of this embodiment are spliced, the precision of the assembled mask is much higher than that of the integrally formed mask with an abnormal shape.

With the mask provided by the embodiment of the present disclosure, in order to reduce the waste of resources caused when the mask is fabricated, a set of masks applicable to display panels having various shapes can be provided to enhance compatibility of the masks. The embodiment of the present disclosure replaces the conventional mask which is integrally formed with an abnormal shape, with the splice-type mask having a plurality of components. With the splice-type mask, masks having different shapes may be formed by connecting and laminating the base mark unit 1 and the connecting members 2 having different shapes. When a shape of a display panel is changed, it only needs to replace a connecting member 2 with a different one to form a shape that is necessary for a new display panel, and then the base mark unit 1 and the connecting members 2 are assembled to form a mask suitable for the new display panel, thereby saving mask manufacturing resources. In addition, more and more display panels are designed to have abnormal shapes, such as a standard rounded corner shape, a multiple-arcs connection shape, and the like. The existence of the abnormal shape destroys the overall symmetry of the mask, which makes it difficult to control the tensile stretching effect of the region having the abnormal shape when the mask is produced, thereby increasing the difficulty in production and easily resulting in that the precision for the region in an abnormal shape in the integrally formed mask with the abnormal shape is poorly controlled. A separate base mark unit and a separate connecting member are manufactured with less difficulty than that for the integrally formed mask with the abnormal shape, so their separate precision and precision after the assembling are much higher than the precision of the integrally formed mask with the abnormal shape. Therefore, as for the abnormal shape, the precision of the splice-type mask is much higher than that of the integrally formed mask. In this way, the precision of the mask itself is improved, leading to an effect of reducing an area of a reserved edge, and narrowing borders of the display panel in total. Thereby, a smooth transition can be achieved between a border of a region with an abnormal shape and a border of a normal region with the above described regular shape, resulting in a harmonious appearance.

Based on the above-described embodiment, another embodiment of the present disclosure further provides another mask, as shown in FIGS. 5-13.

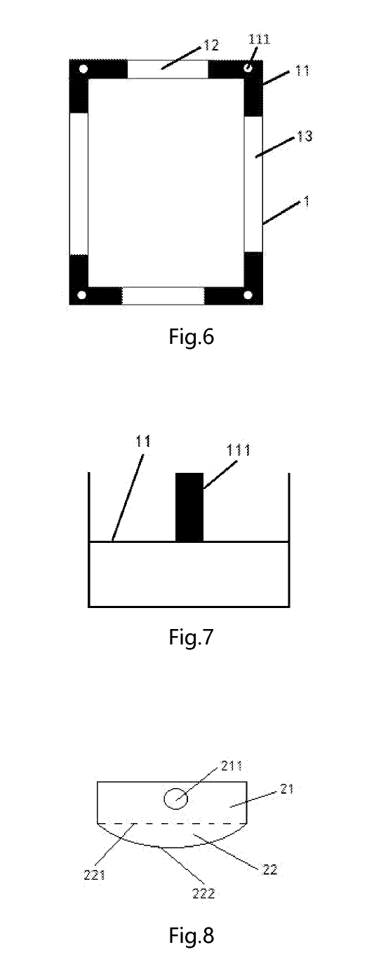

The mask includes a base mark unit 1 and at least one connecting member 2, which are disposed in a laminating manner. As shown in FIGS. 5 and 6, the base mark unit 1 has four borders, a shape of which is the same as that of borders of a standard mask. As shown in FIG. 5, a groove is disposed on an upper surface of a first border 12, a region where the groove is located is a first connecting region 11, and a length of the groove along the extending line direction of the first border 12 is smaller than a length of the first border 12. A width of the groove is equal to a width of the first border 12, and a depth of the groove is less than a thickness of the first border 12. Alternatively, as shown in FIG. 6, the first border 12 is connected to a second border 13, and the first connecting region 11 is a groove that is disposed on an upper surface at corner connection between the first border 12 and the second border 13, a length of the groove on the first border 12 is less than the length of the first border 12, a width of the groove is equal to the width of the first border 12, a depth of the groove is less than the thickness of the first border 12, a length of the groove on the second border 13 is less than a length of the second border 13, a width of the groove on the second border 13 is equal to a width of the second border 13, and a depth of the groove on the second border 13 is less than a thickness of the second border 13. The depths of the groove on the first border 12 and the second border 13 may be the same or different.

Further, the first connecting region 11 is disposed thereon with a first positioning device 111, which may be a protrusion portion disposed at a bottom surface of the groove and having a height less than or equal to the depth of the groove. As shown in FIG. 7, the first positioning device 111 is a cylinder on the bottom surface of the groove, which is obtained by etching and has a height equal to the depth of the groove.

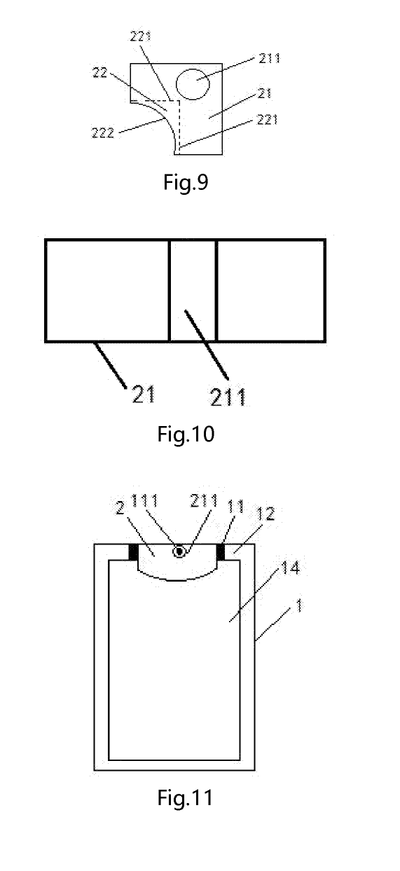

As shown in FIGS. 8 and 9, the connecting member 2 includes a second connecting region 21 and a non-connecting region 22. The first connecting region 11 of the base mark unit 1 is connected to the second connecting region 21 of the connecting member 2. The first connecting region 11 and the second connecting region 21 can be attached in a detachable connection manner to facilitate disassembly of the connecting member 2 from the mask. For example, the first connecting region 11 and the second connecting region 21 are attached in a manner of adhesion or engagement.

A shape of the non-connecting region 22 is composed of a first side 221 and a second side 222. The first side 221 is the boundary between the non-connecting region 22 and the second connecting region 21. The second side 222 is a side having a preset radian, which is set based on a shape of a portion in an abnormal shape of a display panel. As shown in FIG. 8, the second side 222 is formed into a convex arc of the connecting member 2. As shown in FIG. 9, the second side 222 is formed into a concave arc of the connecting member 2.

Further, a second positioning device 211 is disposed on the second connecting region 21 to match with the first positioning device 111 of the first connecting region 11. Specifically, as shown in FIG. 10, the second connecting region 21 has a thickness same as the depth of the groove, and the second positioning device 211 of the second connecting region 21 is a through hole fitting the positioning protrusion portion. The through hole penetrates through the connecting member 2 so as to determine a mounting position of the connecting member 2 based on relative positions of a center of the through hole and a center of the positioning protrusion portion. A radius of the through hole is larger than a radius of the positioning protrusion portion, and the positioning protrusion portion can be inserted into the through hole so that the second connecting region 21 may be completely inserted into the groove, thereafter, a superposed thickness of the first connecting region 11 and the second connecting region 21 does not exceed a thickness of other regions without a groove in the base mark unit 1, thereby preventing a thickness difference from destroying the overall shape of the attached first connecting region 11 and the second connecting region 21. A difference between a height of the positioning protrusion portion and a depth of the through hole is smaller than a first threshold, and a difference between the radius of the positioning protrusion portion and the radius of the through hole is smaller than a second threshold. The first threshold and the second threshold are preset empirical values that avoid the following situation. When the positioning protrusion portion and the through hole are performed a match for positioning, if a volume of the positioning protrusion portion is much smaller than a volume of the through hole, the positioning protrusion portion has a large movable range in the through hole, and is easily displaced when affected by an external force, thereby causing the connecting member 2 to be displaced.

Further, alternatively, as for the positioning devices of the base mark unit 1 and the connecting member 2, the positioning protrusion portion is disposed on the bottom surface of the groove of the base mark unit 1, and the height of the positioning protrusion portion is smaller than the thickness of the second connecting region 21. In the second connection area 21, an alignment recess portion matching the positioning protrusion is provided. Like the arrangement requirements for the positioning protrusion portion and the through hole above-described, a depth of the alignment recess portion is greater than or equal to the protrusion height of the positioning protrusion portion, and a length and a width of the alignment recess portion are greater than a length and a width of the positioning protrusion portion. A positioning mark of a center position of the alignment recess portion is made on an upper surface of the second connecting region 21, in order to determine the mounting position of the connecting member 2 based on relative positions of the positioning mark and a center point on an upper surface of the positioning protrusion portion.

When the connecting member 2 is mounted, the positioning protrusion portion may pass through the through hole to determine the mounting position of the connecting member 2. The positioning protrusion portion may be designed into a shape such as a cylinder, a cube, a cuboid, or the like, and the shape of the positioning protrusion portion is not specifically limited in this embodiment.

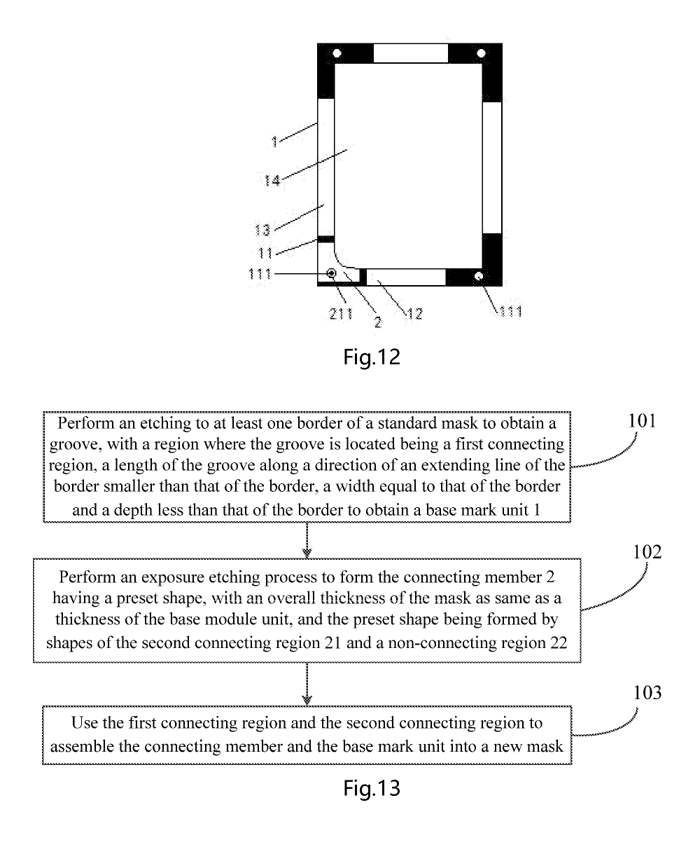

When the connecting member 2 as shown in FIG. 8 is connected to an upper border of the base mark unit 1 as shown in FIG. 5, a mask having an arc-shaped protrusion as shown in FIG. 11 can be formed. When the connecting member 2 shown in FIG. 9 is connected to a corner of the borders of the base mark unit 1 as shown in FIG. 6, a mask having an arc-shaped corner as shown in FIG. 12 can be formed.

In the mask provided in the embodiment of the present disclosure, the groove is disposed on the border of the base mark unit 1, and the connecting member 2 is installed in the groove so that the overall thickness of the assembled mask is the same as the thickness of the base mark unit 1, which avoids increasing the local shadow of the mask due to the connecting member 2. The preset radian is set based on the shape of the display panel, and the concave arc or the convex arc of the connecting member 2 is formed according to the preset radian, so as to obtain a mask having an arc-shaped corner or a mask having an arc-shaped protrusion that meet the requirements of the display panel by using the connecting member 2. Moreover, in order to facilitate disassembly of the components from the mask, the detachable connection manner is used in this embodiment as the manner for attaching the first connecting region 11 and the second connecting region 21. At the same time, in order to improve the accuracy of assembling the base mark unit 1 and the connecting member 2, positioning devices are provided on the base mark unit 1 and the connecting member 2 in the present embodiment, and the two positioning devices are matched for positioning in such a manner that the first connecting region 11 and the second connecting region 21 may be accurately attached together to avoid the installation displacement.

Based on the above-described embodiment, an embodiment of the present disclosure further provides a method of manufacturing a mask. Referring to FIG. 13, the method includes the following steps.

In step 101, a first connecting region 11 on a standard mask is etched to obtain a base mark unit 1.

The base mark unit 1 has the same shape as that of the standard mask, so that the base mark unit 1 may be formed by modifying the standard mask. Moreover, by using the standard mask to fabricate the base mark unit 1, a precision of the base mark unit 1 can be kept the same as that of the standard mask, and the precision thereof is far greater than a precision of an integrally formed mask with an abnormal shape. The first connecting region 11 on the standard mask is etched to obtain at least one region that may be connected to the connecting member 2. Specifically, an etching process, such as a photolithographic etching process may be performed at a position where the first connecting region 11 needs to be disposed in the standard mask, so as to etch away part of the mask at this position and form a groove in the first connecting region 11.

In step 102, a patterning process is performed to fabricate the connecting member 2 having a second connecting region 21, wherein the second connecting region 21 is to be connected to the first connecting region 11.

A shape of the second connecting region 21 of the connecting member 2 is patterned in advance according to a shape of the first connecting region 11 of the base mark unit 1. A shape of a non-connecting region 22 of the connecting member 2 is patterned according to a difference between a target shape and the shape of the base mark unit 1. When the connecting member 2 is manufactured, the connecting member 2 is fabricated by using a patterning process based on a preset pattern so that the separate connecting member 2 may have an abnormal shape that may compensate for the difference, and have a connecting region that can be connected to the base mark unit 1 in a laminating manner. Moreover, due to the limitations of the manufacturing processes, a precision of the connecting member 2 that is separately fabricated is much greater than the precision of the integrally formed mask with the abnormal shape.

In step 103, the connecting member 2 and the base mark unit 1 are assembled to form a new mask by using the first connecting region 11 and the second connecting region 21.

The first connecting region 11 is connected to the second connecting region 21, so that the connecting member 2 and the base mark unit 1 are connected together to form a mask having the target shape. When the target shape becomes a new one, it is only required to fabricate a new connecting member 2 based on the new target shape, and the original connecting member 2 is replaced with the new connecting member 2, so that the new connecting member 2 is combined with the base mark unit 1 to form the new target shape. Moreover, in order to maintain the relative positions of the first connecting region 11 and the second connecting region 21 after they are connected, the first connecting region 11 and the second connecting region 21 may be attached in an adhesive manner, an engagement manner, or a screwed-connection manner. For example, the first connecting region 11 and the second connecting region 21 can be pasted together by using a high temperature resistant adhesive, which has a melting point of about 100° C., and remains insoluble and invariable in the process of vapor deposition of the mask. In this embodiment, the connection manner of the first connecting region 11 and the second connecting region 21 is not specifically limited.

In the method for manufacturing the mask provided by the embodiment of the present disclosure, in order to reduce the waste of resources caused when the mask is fabricated, there is provided a set of masks that may be applicable to display panels having a variety of shapes so as to increase the compatibility of the mask. The base mark unit 1 is produced by etching a conventional standard mask, and the connecting member 2 having an abnormal shape and being connectable to the base mark unit 1 is obtained by etching. Masks having different shapes can be formed by combining the base mark units 1 and the different connecting members 2. When the display panel becomes a new shape, making a mold for the new shape so as to separately form an integrally formed mask with an abnormal shape is not needed, only replacing an old connecting member 2 with a newly manufactured connecting member 2 is needed to obtain a mask that meets the shape requirements of the different display panel, thereby reducing material utilization amount for the fabricating of a mask, and improving the compatibility of the mask. In addition, the precision of the splice-type mask is much higher than that of the integrally formed mask, the precision of the mask its own is improved, so that smooth transition can be made between the border of the region with an abnormal shape and the border of a normal region, to achieve a harmonious appearance.

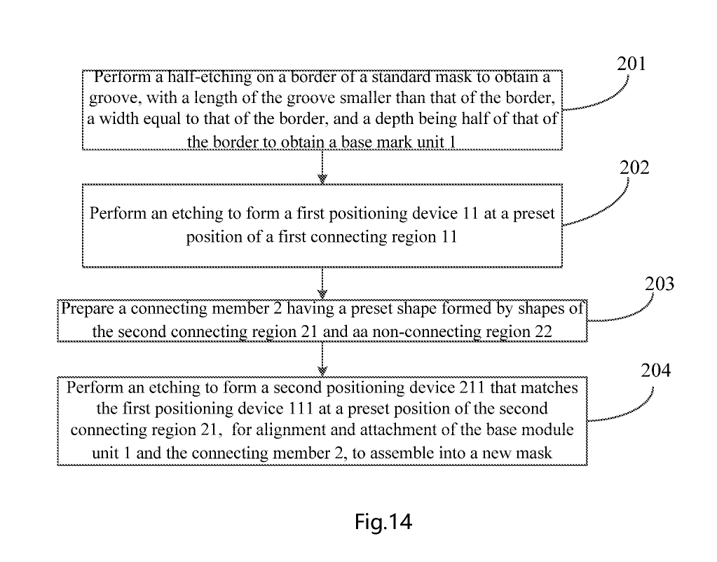

Based on the above-described embodiment, an embodiment of the present disclosure further provides another method for fabricating another mask. Referring to FIG. 14A, the method includes the following steps.

In step 201, etching on at least one border of a standard mask is performed to obtain a groove, wherein a region where the groove is located is a first connecting region, and a length of the groove along a direction of an extending line of the border is smaller than a length of the border, a width of the groove is equal to a width of the border and a depth of the groove is less than a depth of the border to obtain a base mark unit 1.

To avoid increase of a local shadow of the mask after a second connecting region 21 and a first connecting region 11 are connected, the border of the standard mask is etched to obtain the groove so that the connecting member 2 may be inserted into the groove when the connecting member 2 is connected to the first connecting region 11, to reduce a superimposed thickness of the first connecting region 11 and the second connecting region 21.

Further, a half-etching manner is adopted to process the first connecting region 11 on the standard mask in order to facilitate the setting of the etching depth data of the groove and the connecting member. For example, the standard mask has a thickness of 200 μm, and the border of the standard mask is etched to obtain a groove having a depth of 100 μm, a width equal to that of the border and a length less than that of the border so as to obtain a base mark unit 1 having the first connecting region 11.

In step 202, in order to improve the positioning accuracy when the base mark unit 1 and the connecting member 2 are combined, a first positioning device 111 is further formed at the same time when the base mark unit 1 is formed. The positioning device is a positioning protrusion portion formed at a preset position of the first connecting region 11. The preset position includes a bottom surface, a side surface of the first connecting region 11, or the like, and the preset embodiment does not impose any specific limitations on the preset position. The positioning protrusion portion is etched into a shape such as a cylinder, a cube, a cuboid, and the shape of the positioning protrusion portion is not specifically limited in this embodiment. As shown in FIG. 8, a cylinder having a height equal to the depth of the groove is formed as the positioning device of the base mark unit 1 at the bottom of the groove.

In step 203, an exposure etching process is performed to mask material to form the connecting member 2 having a preset shape, wherein an overall thickness of the mask, which is formed by connecting the first connecting region of the base mark unit to the second connecting region of the connecting member, is the same as a thickness of the base module unit, and the preset shape is formed by a shape of the second connecting region 21 and a shape of a non-connecting region 22.

After the base mark unit 1 is fabricated, a thickness of the connecting member 2 is set according to the depth of the groove of the base mark unit 1 so that the superposed thickness of the first connecting region and the second connecting region does not exceed the thickness of the base mold unit. For example, after the base mark unit 1 is manufactured by half-etching, the thickness of the connecting member 2 can be set to be half the depth of the border of the base mark unit 1, that is, the thickness of the connecting member is the same as the depth of the groove, enabling the connecting member 2 to be completely inserted into the groove.

The shape of the connecting member 2 is formed based on the shapes of the second connecting region 21 and the non-connecting region 22, so that the connecting member 2 includes a region in an abnormal shape as same as that of the target shape, and includes a connecting region that may be connected to the base mark unit 1. The connecting member 2 can be connected to the base mark unit 1, and fit with the base mark unit 1 to form the target shape.

In step 204, in order to fit the first positioning device 111 of the first connecting region 11 for positioning, a second positioning device 211 fitting first positioning device 111 is obtained by etching at a preset position of the second connecting region 21. For example, a through hole, which passes through the connecting member and fits the positioning protrusion portion, is obtained by etching at a preset position of the second connecting region 21. The positioning protrusion portion and the through hole serve to align the base mark unit 1 with the connecting member 2 and then attach them.

Specifically, a preset position of the through hole in the second connecting region 21 is set according to a preset position of the positioning protrusion portion. A shape of the through hole matches with the shape of the positioning protrusion portion. For example, if the positioning protrusion portion is a cylinder, the through hole is a cylindrical through hole with a radius larger than a radius of the cylinder; and if the positioning protrusion portion is a cube, the through hole is a through hole shaped like a cube with a side length larger than that of the cube. As shown in FIG. 11, the through hole is a cylindrical through hole. When the first connecting region 11 of the base mark unit 1 is connected to the second connecting region 21 of the connecting member 2, the projection of a center of circle of the through hole on the positioning protrusion portion coincides with a center of circle of the positioning protrusion portion, so as to determine a mounting position of the connecting member 2 on the base mark unit 1, thereby improving the positioning accuracy when the base mark unit 1 and the connecting member 2 are combined.

The first connecting region and the second connecting region are used to assemble the connecting member and the base mark unit into a new mask.

When the first connecting region 11 of the base mark unit 1 is connected to the second connecting region 21 of the connecting member 2, the base mark unit 1 and the connecting member 2 are positioned by the positioning devices, and then the base mark unit 1 and the connection member 2 are connected in a laminating manner based on the positioning, so as to form a new mask with a required shape.

In the method for fabricating the mask provided by the embodiment of the present disclosure, the border of the standard mask is etched to form the groove so as to complete the manufacture of the base mark unit 1; the shape of the connecting member 2 is obtained by etching according to an abnormal shape of the display panel and a shape of the groove, so that the connecting member 2 can be connected to the base mark unit 1 through the groove and form the target shape. Further, with the connecting member 2 which has been etched to the same depth as that of the groove, it is ensured that the overall thickness of the assembled mask is the same as the thickness of the base mark unit 1, so as to avoid a local shadow on the mask. Further, the positioning devices for match are obtained by performing etching in the first connecting region 11 and the second connecting region 21 in order to enable accurate positioning between the components of the mask when the components are assembled to form the mask.

Another embodiment of the present disclosure provides a method of manufacturing a display panel. The display panel includes a display substrate. Before vapor deposition for coating a film on the substrate, according to the requirements of the display panel, the components of the mask in the above-described embodiments are assembled to form a mask that meets the requirements. Specifically, firstly, a series of connecting members 2 are horizontally adsorbed by using a vacuum cup at a time, and then are moved above the first connecting regions 11 of a series of corresponding base mark unit 1, and the connecting members 2 are positioned for installation. Center positions of first positioning devices 111 of the base mark units 1 and second positioning devices 211 of the connecting members 2 are overlapped, and the connecting members 2 and the base mark units 1 are attached to each other based on the positioning. After the attaching is finished, precision measurement may be made on the assembled masks, and an adjustment may be made individually for a connecting region with poor precision. After precision of all the masks meet the requirements, the masks are placed between the substrate formed with a first film and an evaporation source, and the substrate is partially shielded by the masks so that a first pattern is formed on a region 14 of the substrate unshielded by the masks.

Further, the base mark unit 1 and the member may be horizontally attached by a high-temperature resistant adhesive, which is less harmful for the mask, and because the adhesive has a high melting point, it can ensure that the connection member 2 will not fall off during the evaporation of the film. When it is necessary to fabricate a display panel having another shape, the mask is heated at a high temperature to melt the adhesive, and then the connecting member can be conveniently removed by the vacuum suction cup and replaced with a connecting member having another shape.

Another embodiment of the present disclosure provides a display device including a display panel, all the films in which may be manufactured in shapes meeting the requirements by using the masks of the above-described embodiment, so as to form the display panel of the display device.

In the above-described embodiments, as for the descriptions of the embodiments, each has a focus. For the part not described in detail in one embodiment, reference may be made to the relevant descriptions of the other embodiments.

It can be understood that relevant features in the above-described devices can refer to each other. In addition, “first”, “second”, and the like in the above-described embodiments are used to distinguish the embodiments but do not represent the merits of the respective embodiments.

In the description provided herein, a great amount of specific details have been explained. However, it may be understood that the embodiments of the present disclosure may be practiced without these specific details. In some instances, well-known structures and techniques have not been shown in detail in order not to obscure the understanding of this description.

Similarly, it should be understood that in order to streamline the present disclosure and help understanding one or more of the inventive aspects, various features of the present disclosure are sometimes grouped together into a single embodiment, figure, or description thereof in the above description of the exemplary embodiments of the present disclosure. However, the devices of this disclosure should not be interpreted as reflecting an intention that the claimed invention requires more features than those specifically recited in each of the claims. Rather, as reflected in the following claims, inventive aspects lie in not more than all of the features of a single embodiment disclosed above. Thus, the claims following the detailed embodiments are hereby expressly incorporated into the detailed embodiments, with each of the claims serving as a separate embodiment of the present disclosure.

Those skilled in the art can understand that the components in the devices in the embodiments may be adaptively changed to be in one or more devices different from the embodiments. The components in the embodiments may be combined into one component, moreover, the components in the embodiments may be divided into a plurality of sub-components. Except some features that are mutually exclusive, all of the features disclosed in this description (including the appended claims, the abstract, and the drawings), and all of the components of any device so disclosed, may be combined in any manner of combination. Each of the features disclosed in this description (including the appended claims, the abstract, and the drawings) can be replaced with other substitution features that provide the same, equivalent, or similar purpose, unless expressly stated otherwise.

Furthermore, those skilled in the art may understand that although some embodiments described herein include some features included in other embodiments rather than other features, a combination of features of different embodiments is meant to be within the scope of the present disclosure and to form different embodiments. For example, in the following claims, any of the claimed embodiments can be used in any combination.

It should be noted that the above-mentioned embodiments are provided to illustrate the present disclosure but do not limit the present disclosure, and those skilled in the art can design alternative embodiments without departing from the scope of the appended claims. In the claims, reference signs placed within parentheses shall not be construed as limiting the claims. The term “comprising” does not exclude the presence of components or parts not listed in the claims. The term “a” or “an” preceding a component or a part does not exclude the presence of a plurality of such components or parts. The present disclosure may be implemented by means of a device including several different components. In a claim wherein several components are enumerated, some of these components may be embodied by one component. The use of terms “first”, “second”, and “third”, etc. do not denote any order. These terms may be interpreted as names.

The foregoing descriptions are merely preferred embodiments of the present disclosure and are not intended to limit the disclosure in any form. Any simple changes, equivalent variations, and modifications made to the above embodiments according to the technical essence of the present disclosure still fall into the scope of the technical solutions of the present disclosure.

What is claimed is:

1. A mask, comprising:
a base mark unit comprising a first connecting region, and
at least one connecting member laminated to the base mark unit, the connecting member comprising a second connecting region and a non-connecting region,
wherein the first connecting region of the base mark unit is connected to the second connecting region of the connecting member, and a shape of the non-connecting region and a shape of the base mark unit form a desired target shape of the mask.

2. The mask according to claim 1, wherein
the base mark unit comprises at least a first border and a second border connected to the first border; and
a groove is formed on an upper surface of the first border, a region where the groove is located is the first connecting region, a length of the groove along an extending line direction of the first border is smaller than a length of the first border, a width of the groove is equal to a width of the first border, and a depth of the groove is less than a thickness of the first border.

3. The mask according to claim 1, wherein
the base mark unit comprises at least a first border and a second border connected to the first border; and
the first connecting region is a groove formed on an upper surface at corner connection between the first border and the second border, a length of the groove formed on a corresponding border is smaller than a length of the corresponding border, a width of the groove is equal to a width of the corresponding border, and a depth of the groove is less than a thickness of the corresponding border.

4. The mask according to claim 2, wherein
an overall thickness of the mask, which is assembled by connecting the first connecting region of the base mark unit to the second connecting region of the connecting member, is equal to a thickness of the base module unit.

5. The mask according to claim 3, wherein an overall thickness of the mask, which is assembled by connecting the first connecting region of the base mark unit to the second connecting region of the connecting member, is equal to a thickness of the base module unit.

6. The mask according to claim 1, comprising:
a first positioning device provided on the first connecting region; and
a second positioning device provided on the second connecting region, the second positioning device being matched to the first positioning device for positioning such that the first connecting region of the base mark unit and the second connecting region of the connecting member are attached.

7. The mask according to claim 6, wherein
the first positioning device is a positioning protrusion portion, which is disposed on a bottom surface of the groove; and
the second positioning device is a through hole, which matches the positioning protrusion portion and penetrates through the connecting member.

8. The mask according to claim 6, wherein
the first connecting region and the second connecting region are attached in a detachable connection manner.

9. The mask according to claim 6, wherein the first connecting region and the second connecting region are attached in at least one of an adhesive connection manner and an engagement manner.

10. The mask according to claim 1, wherein the shape of the non-connecting region of the connecting member consists of a first side and a second side;
the first side is a boundary between the non-connecting region and the second connecting region; and
the second side is a side having a preset radian.

11. The mask according to claim 10, wherein
the second side of the connecting member is a concave arc, and is connected to a border corner of the base mark unit to form a mask having an arc-shaped corner.

12. The mask according to claim 10, wherein
the second side of the connecting member is a convex arc, and is connected to at least one border of the base mark unit to form a mask having an arc-shaped protrusion.

13. A method of manufacturing a mask, comprising:
performing an etching to a first mask to obtain a base mark unit having a first connecting region;
performing a patterning process to fabricate a connecting member having a second connecting region, wherein the second connecting region is to be connected to the first connecting region; and
assembling the base mark unit and the connecting member by connecting the first connecting region to the second connecting region to form a second mask.

14. The method according to claim 13, wherein the step of performing an etching to a first mask comprises:
performing an etching to at least one border of the first mask to obtain a groove, wherein a region where the groove is located is the first connecting region, and a length of the groove along a direction of an extending line of the border is smaller than a length of the border, a width of the groove is equal to a width of the border, and a depth of the groove is less than a depth of the border to obtain a base mask unit.

15. The method according to claim 14, wherein the step of performing a patterning process to fabricate a connecting member having a second connecting region comprises:
performing an exposure etching process to form the connecting member having a preset shape, the preset shape being formed by a shape of the second connecting region and a shape of the non-connecting region, and
determining a thickness of the connecting member according to the depth of the groove of the base mark unit so that an overall thickness of the mask, which is assembled by the base mark unit and the connecting member, is equal to a thickness of the base mask unit.

16. The method according to claim 13, further comprising:
forming a positioning protrusion portion at a preset position of the first connecting region, the positioning protrusion portion and the base mark unit being formed simultaneously;
performing an etching to obtain a through hole, which matches the positioning protrusion portion and penetrates through the connecting member, at a preset position of the second connecting region, wherein the positioning protrusion portion and the through hole are used for alignment and attachment of the base mark unit and the connecting member.

17. The method according to claim 13, wherein the step of assembling the base mark unit and the connecting member by connecting the first connecting region to the second connecting region to form a second mask comprises:
using a vacuum cup to adsorb the connecting member and then move the connecting member to above the first connecting region of the base mark unit;
overlapping a first position device of the base mark unit and a second positioning device of the connecting member; and
attaching the connecting member and the base mark unit to form the second mask.

18. The method according to claim 17, wherein the step of attaching the connecting member and the base mark unit to form the second mask is made by using a high-temperature resistant adhesive.

19. A method of manufacturing a display panel, which comprises a display substrate, the method comprising:
forming a first film on the display substrate; and
performing a patterning process on the first film by using the mask according to claim 1 to form a first pattern.

20. A display device comprising a display panel, which is manufactured by the method for manufacturing a display panel according to claim 17.
